(19) United States
(12) Patent Application Publication
(10) Pub. No.: US 2022/0359673 A1
(43) Pub. Date: Nov. 10, 2022

(54) LATERALLY DIFFUSED METAL OXIDE SEMICONDUCTOR DEVICE AND MANUFACTURING METHOD THEREOF

(71) Applicant: CSMC TECHNOLOGIES FAB2 CO., LTD., Wuxi (CN)

(72) Inventors: Jingchuan ZHAO, Wuxi (CN); Zhili ZHANG, Wuxi (CN); Sen ZHANG, Wuxi (CN)

(21) Appl. No.: 17/623,485

(22) PCT Filed: May 26, 2020
(86) PCT No.: PCT/CN2020/092293

§ 371 Date: Dec. 28, 2021

(30) Foreign Application Priority Data
Aug. 2, 2019 (CN) 201910712108.6

(51) Int. Cl. H01L 29/40; H01L 29/78; H01L 29/06; H01L 29/10; H01L 29/66

(52) U.S. Cl. CPC H01L 29/404; H01L 29/7816; H01L 29/0653; H01L 29/1095; H01L 29/407; H01L 29/401; H01L 29/66681

(57) ABSTRACT

A laterally diffused metal oxide semiconductor device and a manufacturing method thereof. The device includes: a substrate of a second conductivity type; a drift region arranged on the substrate and of a first conductivity type; a source region of the first conductivity type; a drain region of the first conductivity type; and a longitudinal floating field plate structure arranged between the source region and the drain region and including a dielectric layer arranged on an inner surface of a trench and polysilicon filling the trench. The trench extends from an upper surface of the drift region downward through the drift region into the substrate. At least two longitudinal floating field plate structures are provided, and at least two of the longitudinal floating field plate structures are located at different positions in a length direction of a conductive channel.

### TECHNICAL FIELD

The present disclosure relates to the field of semiconductor manufacturing, and in particular, to a laterally diffused metal oxide semiconductor device and also to a manufacturing method of a laterally diffused metal oxide semiconductor device.

### BACKGROUND

In order to increase a breakdown voltage (BV) of a device and reduce an on-resistance RDS (on), a field plate technology is a common structure for laterally diffused metal oxide semiconductor (LDMOS) devices.

### SUMMARY

Based on the above, there is a need to provide a laterally diffused metal oxide semiconductor device having a new field plate structure and a manufacturing method thereof, so as to increase a breakdown voltage of the device.

A laterally diffused metal oxide semiconductor device, including: a substrate of a second conductivity type; a drift region arranged on the substrate and of a first conductivity type, the first conductivity type and the second conductivity type being opposite conductivity types; a source region of the first conductivity type; a drain region of the first conductivity type; and a longitudinal floating field plate structure arranged between the source region and the drain region and including a dielectric layer arranged on an inner surface of a trench and polysilicon filling the trench, the trench extending from an upper surface of the drift region downward through the drift region into the substrate, at least two longitudinal floating field plate structures being provided, and at least two of the longitudinal floating field plate structures being located at different positions in a length direction of a conductive channel.

A manufacturing method of a laterally diffused metal oxide semiconductor device, configured to manufacture the laterally diffused metal oxide semiconductor device according to any one of the foregoing.

Details of one or more embodiments of the present disclosure are set forth in the following accompanying drawings and descriptions. Other features, objectives, and advantages of the present disclosure become obvious with reference to the specification, the accompanying drawings, and the claims.

### BRIEF DESCRIPTION OF THE DRAWINGS

In order to better describe and illustrate embodiments and/or examples of those inventions disclosed herein, reference may be made to one or more accompanying drawings.

Additional details or examples used to describe the accompanying drawings should not be considered as limitations on the scope of any of the disclosed inventions, the presently described embodiments and/or examples, and the presently understood best mode of these inventions.

FIG. 1 is a schematic cross-sectional view of a laterally diffused metal oxide semiconductor device according to an embodiment;

FIG. 2 is a perspective view of the structure shown in FIG. 1;

FIG. 3 is a layout of partial layers of the laterally diffused metal oxide semiconductor device according to an embodiment:

FIG. 4 is an enlarged partial view of a region 12 shown in FIG. 3;

FIG. 5 is a schematic diagram of distribution of longitudinal floating field plate structures according to an embodiment different from that of FIG. 4:

FIG. 6 is a schematic diagram of distribution of the longitudinal floating field plate structures according to another embodiment;

FIG. 7 is a scanning electron microscope (SEM) diagram of a section of the longitudinal floating field plate structures according to an embodiment;

FIG. 8 is a graph of an OFF breakdown voltage of the laterally diffused metal oxide semiconductor device in the embodiment shown in FIG. 7;

FIG. 9 is a flowchart of a manufacturing method of a laterally diffused metal oxide semiconductor device according to an embodiment; and

FIG. 10 is a diagram of substeps of step S220 according to an embodiment.

### DETAILED DESCRIPTION OF THE EMBODIMENTS

For easy understanding of the present invention, a more comprehensive description of the present invention is given below with reference to the accompanying drawings. Preferred embodiments of the present invention are given in the accompanying drawings. However, the present invention may be implemented in many different forms and is not limited to the embodiments described herein. Rather, these embodiments are provided to understand the disclosed content of the present invention more thoroughly and comprehensively.

The vocabulary in the semiconductor field used herein is a technical vocabulary commonly used by those skilled in the art. For example, for P-type and N-type impurities, in order to distinguish doping concentration, it is simple to use P+ type to represent P type of heavy doping concentration, use P type to represent P type of medium doping concentration, use P− type to represent P type of light doping concentration, use N+ type to represent N type of the heavy doping concentration, use N type to represent N type of the medium doping concentration, and use N− type to represent N type of the light doping concentration.

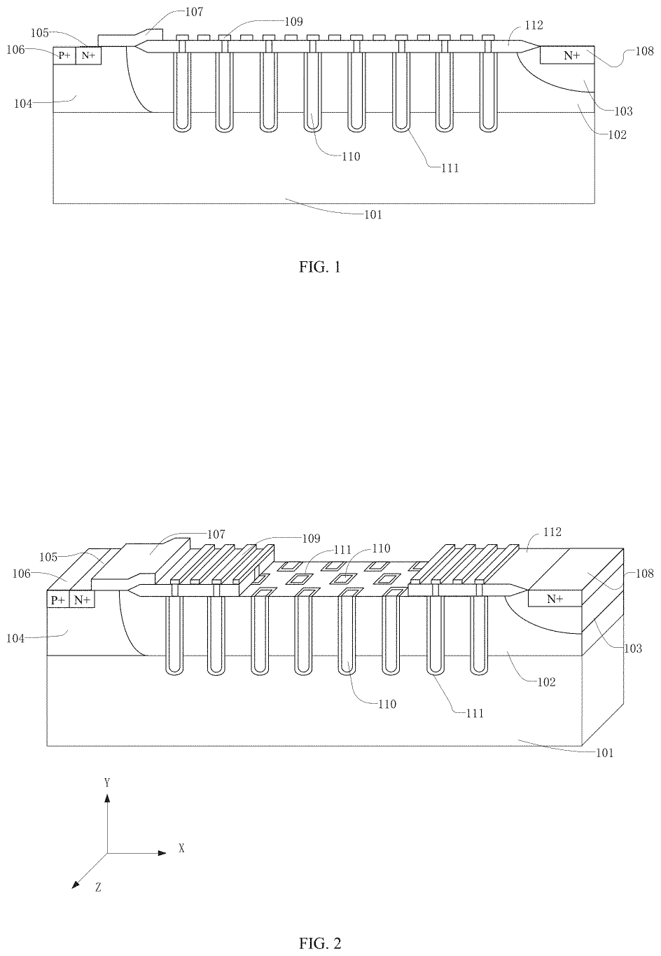

FIG. 1 is a schematic cross-sectional view of a laterally diffused metal oxide semiconductor (LDMOS) device according to an embodiment. FIG. 2 is a perspective view of the structure shown in FIG. 1. In the embodiments shown in FIG. 1 and FIG. 2, the laterally diffused metal oxide semiconductor device includes a substrate 101, a drift region 102, a source region 105, a drain region 108 and a longitudinal floating field plate structure. As known by those skilled in the art, “floating” means that the field plate is not connected to external potential. FIG. 1 and FIG. 2 are embodiments of an NLDMOS. The substrate 101 is a P-type substrate, and the drift region 102 is an N-type drift region arranged on the substrate 101. The longitudinal floating field plate structure is arranged between the N-type source region 105 and the N-type drain region 108 and includes a dielectric layer 111 arranged on an inner surface of a trench and polysilicon 110 filling the trench. The trench extends from an upper surface of the drift region 102 downward through the drift region 102 into the substrate 101. In the embodiment shown in FIG. 2, an X axis is a length direction of a conductive channel, an Z axis is a width direction of the conductive channel, and a Y axis is a vertical direction of the device. At least two longitudinal floating field plate structures are provided, and at least two of the longitudinal floating field plate structures are located at different positions in the length direction of the conductive channel (that is, two longitudinal floating field plate structures have different X-axis coordinates). As can be seen from FIG. 2, the longitudinal floating field plate structures are arranged in three dimensions.

According to the laterally diffused metal oxide semiconductor device and the manufacturing method thereof, two longitudinal floating field plate structures located at different positions in a length direction of a conductive channel form a parallel plate capacitor, so as to divide a voltage of the device, thereby improving an electric field in the drift region and increasing a withstand voltage (breakdown voltage) of the device.

In one embodiment, in order to obtain a higher breakdown voltage, the substrate 101 may be made of a substrate material with higher resistivity to achieve substrate depletion.

In one embodiment, the drift region 102 is formed by high temperature driving-in after ion implantation, which has to reach a certain depth to ensure substrate depletion of the device and a current conduction path.

In one embodiment, the longitudinal floating field plate structures form a multi-row and multi-column array structure. Referring to FIG. 2, in the embodiment, in the array structure, a row direction is the length direction of the conductive channel (X-axis direction) and a column direction is the width direction of the conductive channel (Z direction).

In the embodiments shown in FIG. 1 and FIG. 2, the laterally diffused metal oxide semiconductor device further includes a field oxide layer 112, a gate 107 and a substrate leading-out region 106. The field oxide layer 112 is arranged on the drift region 102. The gate 107 made of a polysilicon material extends from a position of the field oxide layer 112 adjacent to the source region 105 to the source region 105. The substrate leading-out region 106 is a P-type doped region, arranged on one side of the source region 105 away from the gate 107 and is in contact with the source region 105.

In the embodiments shown in FIG. 1 and FIG. 2, the source region 105 and the substrate leading-out region 106 are arranged in a second-conductivity-type well region 104, and the drain region 108 is arranged in a first-conductivity-type well region 103. In the embodiments shown in FIG. 1 and FIG. 2, the first-conductivity-type well region 103 is an N well, and the second-conductivity-type well region 104 is a P well. The first-conductivity-type well region 103 acts as a buffer layer in the drift region at a drain end, which improves an ON breakdown voltage of LDMOS during forward operation. The second-conductivity-type well region 104 acts as a channel forming region of the device, with a concentration affecting depletion and an on-voltage of the drift region.

In the embodiments shown in FIG. 1 and FIG. 2, the laterally diffused metal oxide semiconductor device further includes a plurality of conductive equipotential strips 109 arranged on the field oxide layer 112. Each of the conductive equipotential strips 109 extends along the width direction of the conductive channel (i.e., the Z-axis direction in FIG. 2), and each of the conductive equipotential strips 109 passes downward through the field oxide layer 112 through a contact hole filled with a conductive material to be electrically connected to one column of longitudinal floating field plate structures below, so as to pull bottom potentials of the connected longitudinal floating field plate structures to be equal to a surface potential. In one embodiment, the conductive equipotential strip 109 is made of a metal material. The conductive equipotential strip 109 may be formed by a common aluminum or copper interconnection process.

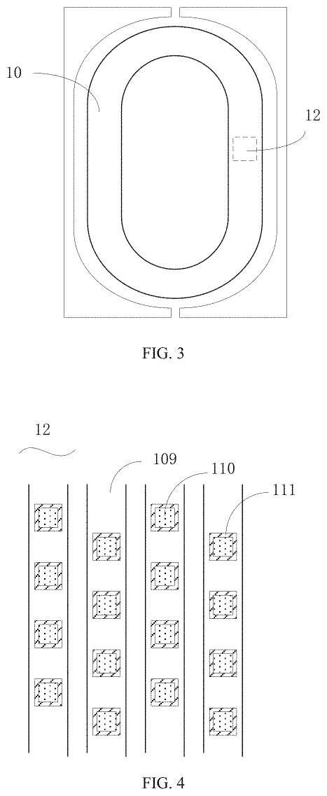

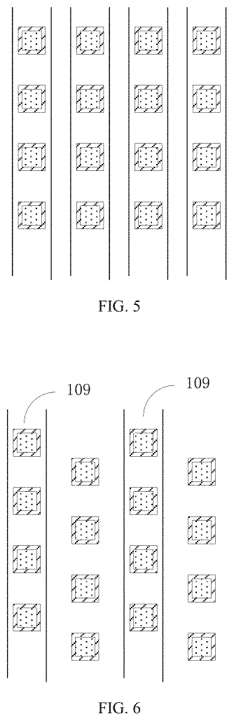

In one embodiment, each of the conductive equipotential strips 109 is an equipotential ring enclosing a runway structure on a layout. Referring to FIG. 3, a position of each conductive equipotential strip 109 is a runway region 10. FIG. 4 is an enlarged view of a region 12 in FIG. 3. In the embodiment shown in FIG. 4, the longitudinal floating field plate structures in even columns are staggered with those in odd columns. In other embodiments, the longitudinal floating field plate structures may also be arranged side by side, as shown in FIG. 5.

In one embodiment, the conductive equipotential strips 109 are arranged every other column, and only one of every two columns of longitudinal floating field plate structures is provided with the conductive equipotential strips. For example, the conductive equipotential strips are arranged in the odd columns but not in the even columns; or the conductive equipotential strips are arranged in the even columns but not in the odd columns.

In one embodiment, floating field plates are at an equal column spacing. That is, spacings in the X-axis direction in FIG. 2 are equal. The equal column spacing enables the capacitance between two adjacent longitudinal floating field plate structures to be equal.

In one embodiment, the polysilicon 110 in the longitudinal floating field plate structure is doped polysilicon. The polysilicon 110 at a certain doping concentration penetrates from a surface of the device to the substrate 101, so that the surface of the device and the substrate 101 have an equal potential. In this way, a bottom potential of the longitudinal floating field plate structure is limited by the surface of the device, so as to improve stability of the device. In one embodiment where the laterally diffused metal oxide semiconductor device is an NLDMOS, the polysilicon 110 is N-type doped polysilicon.

In one embodiment, the dielectric layer 111 in the longitudinal floating field plate structure is made of silicon oxide, such as silicon dioxide. The dielectric layer 111 is arranged on an inner wall of the trench. Charges between doped ions in the drift region 102 and the longitudinal floating field plate structure are balanced more easily. Distributed peak values of the electric field are transferred from a junction of the substrate 101 and the drift region 102 to a bottom end of the longitudinal floating field plate structure in the substrate 101, which may effectively prevent advance breakdown of the device in the case of a reverse withstand voltage.

Each two adjacent longitudinal floating field plate structures along the X axis may be regarded as a pair of parallel plate capacitors, and their potential difference is a constant. A withstand voltage of the device increases with an increase in a number of the longitudinal floating field plate structures. Therefore, the number of the longitudinal floating field plate structures may be set according to a breakdown voltage value required by the device.

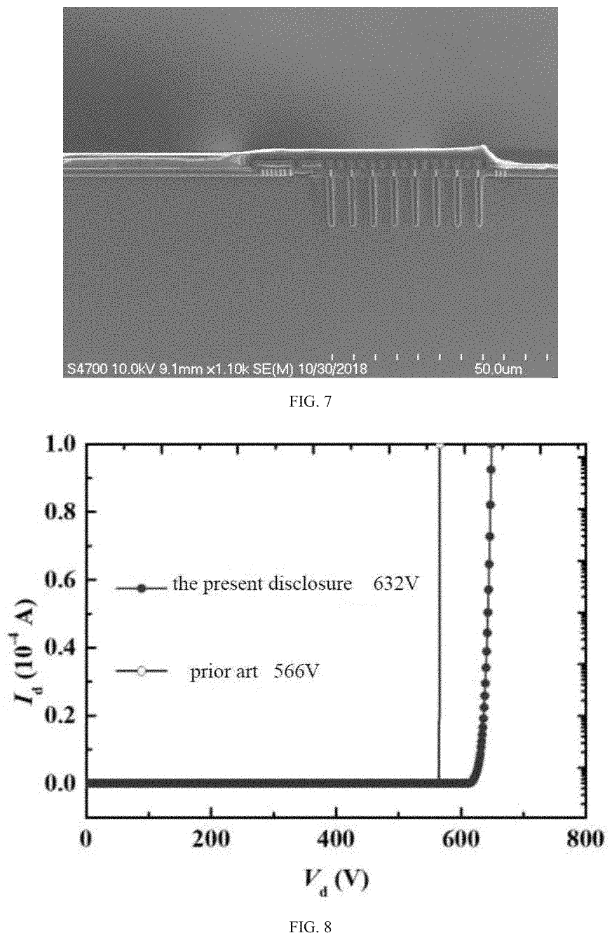

FIG. 7 is an SEM diagram of a section of the longitudinal floating field plate structure according to another embodiment. FIG. 8 is a graph of an OFF breakdown voltage of the laterally diffused metal oxide semiconductor device in the embodiment shown in FIG. 7. In FIG. 8, the abscissa is a device drain voltage and the ordinate is a device drain current. As can be seen, an exemplary OFF breakdown voltage in the related art is about 566 V, while with the addition of the longitudinal floating field plate structure according to the present disclosure, the OFF breakdown voltage is about 632 V, increased by 11.7%.

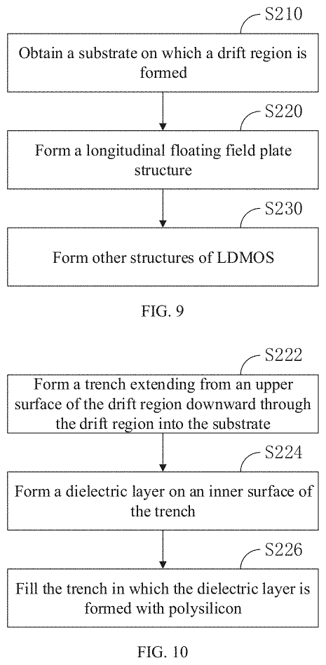

The present disclosure further provides a manufacturing method of a laterally diffused metal oxide semiconductor device, configured to manufacture the laterally diffused metal oxide semiconductor device described above. FIG. 9 is a flowchart of a manufacturing method of a laterally diffused metal oxide semiconductor device according to an embodiment, including the following steps.

In S210, a substrate on which adrift region is formed is obtained.

The drift region of a first conductivity type is formed on the substrate of a second conductivity type. In this embodiment, the laterally diffused metal oxide semiconductor device is an NLDMOS device. The first conductivity type is N-type, and the second conductivity type is P-type. In other embodiments, the first conductivity type is P-type, and the second conductivity type is N-type.

In S220, a longitudinal floating field plate structure is formed.

The longitudinal floating field plate structure is formed between a source region and a drain region. At least two longitudinal floating field plate structures are provided, and at least two of the longitudinal floating field plate structures are located at different positions in a length direction of a conductive channel.

In S230, other structures of LDMOS are formed.

After the formation of a floating field plate, other structures of LDMOS are formed. In one embodiment, S230 may be performed according to the related art.

As shown in FIG. 10, in one embodiment, step S220 specifically includes the following steps.

In S222, a trench extending from an upper surface of the drift region downward through the drift region into the substrate is formed.

In one embodiment, the trench is formed by an etch process.

In S224, a dielectric layer is formed on an inner surface of the trench.

In one embodiment, through thermal oxidation, an oxide layer with a certain thickness is formed on the inner wall of the trench as the dielectric layer.

In S226, the trench in which the dielectric layer is formed is filled with polysilicon.

In one embodiment, the trench is filled with polysilicon with certain doping concentration by a deposition process.

In one embodiment, step S230 includes:

forming a first-conductivity-type well region and a second-conductivity-type well region. The first-conductivity-type well region acts as a buffer layer in the drift region at a drain end, which improves an ON breakdown voltage of LDMOS during forward operation. The second-conductivity-type well region acts as a channel forming region of the device, with a concentration affecting depletion and an on-voltage of the drift region. In this embodiment, the first-conductivity-type well region is an N well, and the second-conductivity-type well region is a P well.

A field oxide layer is formed on the drift region.

A gate is formed. In this embodiment, the gate is made of a polysilicon material and extends from an edge of the field oxide layer over the second-conductivity-type well region.

A source region, a drain region and a substrate leading-out region are formed. Through an ion implantation process, the source region and the substrate leading-out region are formed in the second-conductivity-type well region, and the drain region is formed in the first-conductivity-type well region. In this embodiment, the source region and the drain region are N+ doped regions, and the substrate leading-out region is a P+ doped region.

An interlayer dielectric layer is formed. The interlayer dielectric layer (ILD) is formed on a wafer surface obtained in the previous step.

A contact hole is formed. The contact hole through the ILD may be formed by an etch process in a structure required to be led out to the surface of the device.

Conductive equipotential strips and gate, drain and source metal electrodes are formed. In this embodiment, the conductive equipotential strips are metal equipotential rings and may therefore be formed with the gate, drain, and source metal electrodes.

The above embodiments only describe several implementations of the present invention, which are described specifically and in detail, and therefore cannot be construed as a limitation on the patent scope of the present invention. It should be pointed out that those of ordinary skill in the art may also make several changes and improvements without departing from the ideas of the present invention, all of which fall within the protection scope of the present invention. Therefore, the patent protection scope of the present invention shall be subject to the appended claims.

1. A laterally diffused metal oxide semiconductor device, comprising:
a substrate of a second conductivity type;
a drift region arranged on the substrate and of a first conductivity type, the first conductivity type and the second conductivity type being opposite conductivity types;
a source region of the first conductivity type;
a drain region of the first conductivity type; and
a longitudinal floating field plate structure arranged between the source region and the drain region and comprising a dielectric layer arranged on an inner surface of a trench and polysilicon filling the trench, the trench extending from an upper surface of the drift region downward through the drift region into the substrate, at least two longitudinal floating field plate structures being provided, and at least two of the longitudinal floating field plate structures being located at different positions in a length direction of a conductive channel.

2. The laterally diffused metal oxide semiconductor device according to claim 1, wherein the longitudinal floating field plate structures are arranged to form an array structure.

3. The laterally diffused metal oxide semiconductor device according to claim 2, wherein in the array structure, a row direction is the length direction of the conductive channel and a column direction is a width direction of the conductive channel.

4. The laterally diffused metal oxide semiconductor device according to claim 3, further comprising:
a field oxide layer arranged on the drift region;
a gate extending from a position of the field oxide layer adjacent to the source region to the source region; and
a substrate leading-out region of the second conductivity type, arranged on one side of the source region away from the gate and in contact with the source region.

5. The laterally diffused metal oxide semiconductor device according to claim 4, further comprising a plurality of conductive equipotential strips arranged on the field oxide layer; each of the conductive equipotential strips extending along the width direction of the conductive channel and passing downward through the field oxide layer through a conductive structure to be electrically connected to one column of longitudinal floating field plate structures below, so as to pull bottom potentials of the column of longitudinal floating field plate structures to be equal to a surface potential.

6. The laterally diffused metal oxide semiconductor device according to claim 5, wherein each of the conductive equipotential strips is an equipotential ring enclosing a runway structure on a layout.

7. The laterally diffused metal oxide semiconductor device according to claim 5, wherein the conductive equipotential strips are arranged every other column, and no conductor leading-out the longitudinal floating field plate structure is arranged above a column of longitudinal floating field plate structures separated by two columns of conductive equipotential strips.

8. The laterally diffused metal oxide semiconductor device according to claim 5, wherein the conductive equipotential strip is made of a metal material.

9. The laterally diffused metal oxide semiconductor device according to claim 3, wherein the longitudinal floating field plate structures in even columns are staggered with those in odd columns.

10. The laterally diffused metal oxide semiconductor device according to claim 2, wherein the floating field plates are at an equal column spacing.

11. The laterally diffused metal oxide semiconductor device according to claim 1, wherein the polysilicon is doped polysilicon.

12. The laterally diffused metal oxide semiconductor device according to claim 1, wherein the dielectric layer is made of silicon oxide.

13. The laterally diffused metal oxide semiconductor device according to claim 1, wherein the first conductivity type is N-type, and the second conductivity type is P-type.

14. The laterally diffused metal oxide semiconductor device according to claim 1, further comprising a first-conductivity-type well region and a second-conductivity-type well region, the drain region being arranged in the first-conductivity-type well region, and the source region and the substrate leading-out region being arranged in the second-conductivity-type well region.

15. A manufacturing method of a laterally diffused metal oxide semiconductor device, configured to manufacture the laterally diffused metal oxide semiconductor device according to claim 1.
